(19) United States
(12) Patent Application Publication
(10) Pub. No.: US 2013/0020600 A1
(43) Pub. Date: Jan. 24, 2013

(54) LIGHT EMITTING DIODE PACKAGE

(71) Applicant: Cheol Jun YOO, Chungcheongnam-do (KR)

(72) Inventor: Cheol Jun YOO, Chungcheongnam-do (KR)

(73) Assignee: SAMSUNG ELECTRONICS CO., LTD.

(21) Appl. No.: 13/554,765

(22) Filed: Jul. 20, 2012

(30) Foreign Application Priority Data
Jul. 21, 2011 (KR) 10-2011-0072500

(51) Int. Cl. H01L 33/60

(52) U.S. Cl. 257/98; 257/E33.072; 257/E33.073

(57) ABSTRACT

A light emitting diode (LED) package is disclosed. The LED package includes a first metal line layer and a second metal line layer bonded to a circuit substrate, a thin film substrate disposed on the first metal line layer and the second metal line layer and configured to include an opening that exposes the first metal line layer and the second metal line layer, and an LED disposed in the opening and brought into contact with the first metal line layer and the second metal line layer.

### CROSS-REFERENCE TO RELATED APPLICATION

This application claims the benefit to Korean Patent Application No. 10-2011-0072500, filed on Jul. 21, 2011, the disclosure of which is incorporated herein by reference.

### BACKGROUND

1. Field of the Invention

The present invention relates to a light emitting diode (LED) package, and more particularly, to a thinned LED package having a high heat radiation efficiency.

2. Description of the Related Art

Early on, a light emitting diode (LED) package was used for signaling. Recently, application fields of the LED package have widened to a back light unit (BLU), a light source of large-area display devices, such as a liquid crystal display (LCD), lighting devices, and the like. In addition, since the LED has a relatively low power consumption and long lifespan compared to common bulbs or fluorescent lamps, demand for the LED is increasing.

LEDs may be provided in the form of LED packages by being mounted on a package substrate.

For efficient radiation of heat, the LED package may be manufactured in a manner such that an LED is mounted on a heat conductive substrate, such as a ceramic substrate, and the heat conductive substrate is mounted on a circuit substrate. However, in this case, a thickness of the heat conductive substrate may increase the overall thickness of the LED package. That is, miniaturization of the LED package is difficult.

### SUMMARY

An aspect of the present disclosure provides a light emitting diode (LED) package capable of achieving thinning and high heat radiation efficiency by mounting an LED on a thin-film substrate including an opening.

According to an aspect of the present disclosure, there is provided a light emitting diode (LED) package including a first metal line layer and a second metal line layer bonded to a circuit substrate, a thin film substrate disposed on the first metal line layer and the second metal line layer and including an opening that exposes the first metal line layer and the second metal line layer, and an LED disposed in the opening and contacting the first metal line layer and the second metal line layer.

In certain embodiments of the disclosure, the thin film substrate may have a second height equal to or less than a first height, which is the height of the LED.

In certain embodiments of the disclosure, the thin film substrate may have a second height greater than a first height, which is the height of the LED.

The opening may have a second surface area greater than a first surface area which, is the surface area of the LED.

The LED package may further include a light reflective filling material disposed between the opening and the LED.

The light reflective filling material may include an organic or inorganic polymer, a light reflective material, a reinforcing material, an adhesive, and an antioxidant.

The first metal line layer and the second metal line layer may be disposed at a predetermined distance from each other on the circuit substrate.

The first metal line layer and the second metal line layer may each include a plurality of holes disposed on an exposed region of the thin film substrate, exposed through the opening, to expose the circuit substrate.

The first metal line layer and the second metal line layer may be disposed on a front surface of the circuit substrate at a distance from each other, and exposed at uniform intervals along an inside of the opening of the thin film substrate.

The opening may include a first opening to expose the first metal line layer, and a second opening to expose the second metal line layer.

The LED may be disposed in the first opening and electrically connected with the first metal line layer, and also electrically connected with the second metal line layer exposed through the second opening by a wire.

The opening may further include a third opening to expose the first metal line layer.

The LED may be disposed in the first opening and electrically connected with the second metal line layer exposed through the second opening by a first wire, and also electrically connected with the first metal line layer exposed through the third opening by a second wire.

An inner surface of the opening may be inclined toward an upper surface of the thin film substrate.

The LED package may further include a light reflective layer extending from an inner surface of the opening to an upper surface of the thin film substrate.

The LED package may further include a lens unit disposed on the thin film substrate to cover the LED.

The thin film substrate may include any one of a polyimide, an epoxy resin, a silicone resin, polyethylene terephthalate (PET) resin, a polyester resin, and a ceramic.

According to another aspect of the present disclosure, there is provided an LED package including a circuit substrate, a thin film substrate disposed on the circuit substrate and including a first opening and a second opening exposing the circuit substrate, a first metal line layer and a second metal line layer bonded to the thin film substrate and respectively disposed in a first region which includes the first opening and a second region which includes the second opening, a metal bonding layer filling in the first opening and the second opening, thereby electrically connecting the first metal line layer and the second metal line layer with the circuit substrate, and an LED disposed on the first metal line layer and the second metal line layer.

The LED package may further include a metal pattern layer extended from an outer surface of the thin film substrate to inner surfaces of the first opening and the second opening, passing through a bonding surface with respect to the circuit substrate.

The LED package may further include a lens unit disposed on the thin film substrate to cover the LED.

According to another aspect of the present disclosure, there is provided A light emitting diode (LED) package comprising a first metal line layer and a second metal line layer disposed on a circuit substrate. A thin film substrate having at least one opening is disposed on the first metal line layer and the second metal line layer. The at least one opening exposes a portion of the first metal line layer and a portion of the second metal line layer. An LED is disposed in the at least one opening, wherein the LED is in electrical contact with the first metal line layer and the second metal line layer.

In certain embodiments of the present disclosure, the first metal line layer and the second metal line layer are bonded to the circuit substrate via a first metal bonding layer and a second metal bonding layer, respectively.

The circuit substrate may include a first circuit pattern in electrical contact with the first metal line layer and a second circuit pattern in electrical contact with the second metal line layer.

In certain embodiments of the present disclosure, the at least one opening comprises a first opening exposing the first metal line layer and a second opening exposing the second metal line layer.

The LED may be disposed in the first opening and electrically connected with the first metal line layer, and also electrically connected with the second metal line layer exposed through the second opening by a wire.

The at least one opening may further comprise a third opening exposing the first metal line layer.

The LED may be disposed in the first opening and electrically connected with the second metal line layer exposed through the second opening by a first wire, and electrically connected with the first metal line layer exposed through the third opening by a second wire.

### BRIEF DESCRIPTION OF THE DRAWINGS

These and/or other aspects, features, and advantages of the disclosure will become apparent and more readily appreciated from the following description of exemplary embodiments, taken in conjunction with the accompanying drawings of which:

FIGS. 1 to 3 are diagrams illustrating a structure of a light emitting diode (LED) package according to an embodiment of the present disclosure;

FIGS. 4 and 5 are diagrams illustrating a structure of an LED package according to another embodiment of the present disclosure;

FIGS. 6 and 7 are diagrams illustrating a structure of an LED package according to still another embodiment of the present disclosure;

FIGS. 8 to 10 are diagrams illustrating a structure of an LED package according to yet another embodiment of the present disclosure;

FIG. 11 is a diagram illustrating a structure of an LED package according to further another embodiment of the present disclosure;

FIGS. 12 to 14 are diagrams illustrating a structure of an LED package according to still another embodiment of the present disclosure; and

FIGS. 15 and 16 are diagrams illustrating structures of LED packages according to various embodiments of the present disclosure.

### DETAILED DESCRIPTION

Reference will now be made in detail to exemplary embodiments of the present disclosure, examples of which are illustrated in the accompanying drawings, wherein like reference numerals refer to the like elements throughout.

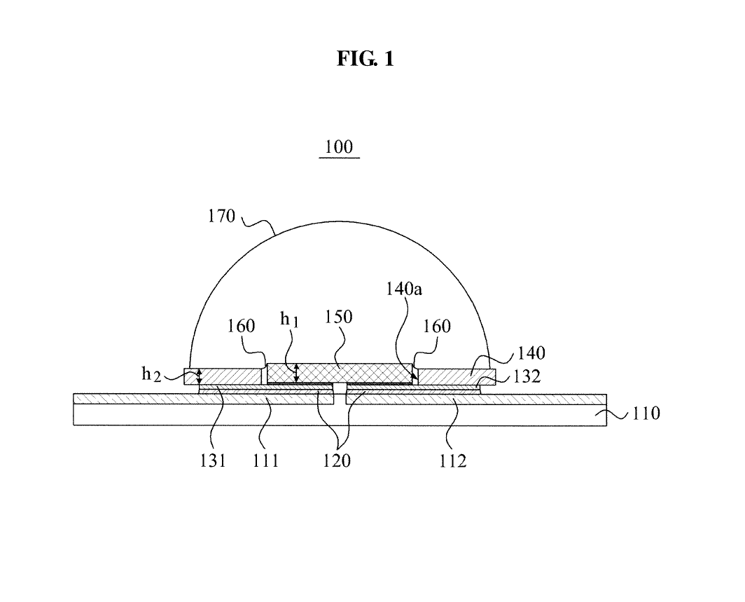

FIGS. 1 to 3 are diagrams illustrating a structure of a light emitting diode (LED) package 100 according to an embodiment of the present disclosure.

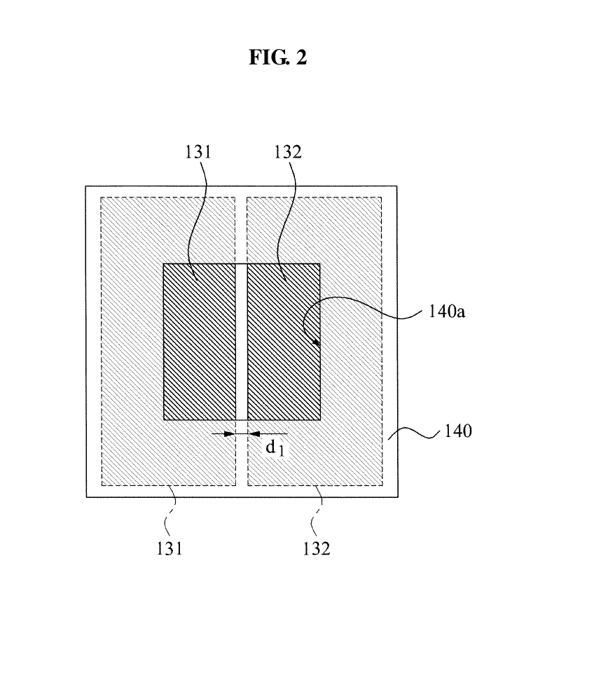

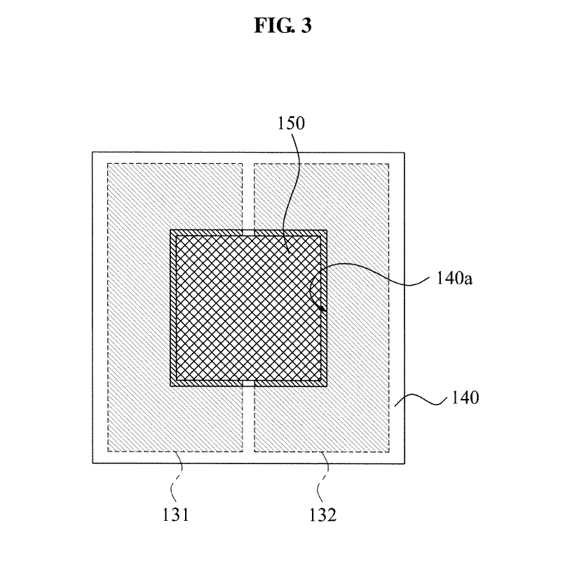

Specifically, FIG. 1 is a sectional view of the LED package 100, FIG. 2 is a plan view showing that a thin film substrate 140 is mounted on a circuit substrate 110, and FIG. 3 is a plan view showing that an LED 150 is mounted on the thin film substrate 140.

Referring to FIG. 1, the LED package 100 includes the circuit substrate 110, a first metal line layer 131, a second metal line layer 132, the thin film substrate 140, the LED 150, a light reflective filling material 160, and a lens unit 170.

The circuit substrate 110 is a package substrate to mount the LED 150 into a package form. The circuit substrate 110 includes circuit patterns 111 and 112 to supply external power to the LED 150.

The first metal line layer 131 and the second metal line layer 132 are bonded onto the circuit substrate 110 by a metal bonding layer 120, and electrically connected with the circuit patterns 111 and 112. The first metal line layer 131 and the second metal line layer 132 may be disposed on a front surface of the circuit substrate 110 and at a predetermined distance from each other. The first metal line layer 131 and the second metal line layer 132 may have the same or differing surface areas.

The thin film substrate 140 may be disposed on the first metal line layer 131 and the second metal line layer 132 by a bonding material. The thin film substrate 140 may include an opening 140a for exposing the first metal line layer 131 and the second metal line layer 132. The opening 140a may be single or plural. A structure of the thin film substrate 140 will be described in detail with reference to FIG. 2.

As shown in FIG. 2, when the thin film substrate 140 is disposed on the circuit substrate 110, the first metal line layer 131 and the second metal line layer 132 are exposed through the opening 140a of the thin film substrate 140. The first metal line layer 131 and the second metal line layer 132 are bonded to the circuit substrate 110 and disposed at a first distance d₁ from each other.

In addition, the first metal line layer 131 and the second metal line layer 132 may not only electrically connect the LED 150 with the circuit patterns 111 and 112 but also perform heat radiation. More specifically, the first metal line layer 131 and the second metal line layer 132 may quickly radiate heat generated from the LED 150 by transferring the heat to the circuit patterns 111 and 112. For this purpose, the first metal line layer 131 and the second metal line layer 132 may be bonded to front surfaces of the circuit patterns 111 and 112.

The LED 150 may be mounted in the opening 140a of the thin film substrate 140 and brought into contact with the first metal line layer 131 and the second metal line layer 132 exposed through the opening 140a. Specifically, as shown in FIG. 3, a first electrode (not shown) and a second electrode (not shown) disposed at the LED 150 may be flip-chip bonded and brought into contact with the first metal line layer 131 and the second metal line layer 132 in a facing manner.

The thin film substrate 140 may have a second height h₂ which is equal to or less than a first height h₁, which is the height of the LED 150.

However, the second height h₂ of the thin film substrate 140 may be greater than the first height h₁ of the LED 150. That is, the LED 150 may be processed to have a height lower than the thin film substrate 140 so that the LED 150 is built in the opening 140a of the thin film substrate 140.

The thin film substrate 140 may be formed of any one selected from a polyimide, an epoxy resin, a silicone resin, polyethylene terephthalate (PET) resin, a polyester resin, and a ceramic. The thin film substrate 140 may further include a glass fiber or a ceramic powder to increase hardness or supplement mechanical property. Furthermore, when made of a ceramic, the thin film substrate 140 may include aluminum oxide (Al₂O₃) or aluminum nitride (AlN). Also, the thin film substrate 140 may further include titanium dioxide (TiO₂) to provide relatively high light reflectivity.

Since the opening 140a is a region for mounting the LED 150, the opening 140a may have a second surface area greater than a first surface area, which is the surface area of the LED 150. Thus, when the opening 140a has the second surface area, a gap is generated between the LED 150 and the opening 140a. The light reflective filling material 160 may fill in the gap.

The light reflective filling material 160 may include an organic or inorganic polymer, a light reflective material, a reinforcing material, an adhesive, and an antioxidant. The light reflective material may be metallic particles having a high light reflectivity. The reinforcing material may be silica for reinforcing the mechanical property. The adhesive may be a silane.

The lens unit 170 may be disposed on the thin film substrate 140 to cover the LED 150.

Although FIG. 1 illustrates a structure where the light reflective filling material 160 is disposed between the opening 140a and the LED 150, the lens unit 170 may fill in the gap between the opening 140a and the LED 150. That is, a transparent resin for forming the lens unit 170 may be applied on the LED 150 to fill in the gap while a dedicated filling material such as the light reflective filling material 160 is omitted.

When a ceramic substrate without an opening is used as a heat radiation substrate as in a conventional LED package, a process of forming a via electrode on the ceramic substrate and a process of forming a metal line layer connected with the via electrode on an upper and lower surface of the ceramic substrate are indispensable. Consequently, the manufacturing process becomes complicated. The ceramic substrate may be damaged or broken during the manufacturing process. In addition, a thickness of the ceramic substrate and a thickness of the metal line layer formed on the upper and lower surface of the ceramic substrate increase the whole thickness of the LED package.

However, as shown in FIGS. 1 to 3, the LED package 100 according to an embodiment of the present disclosure is configured such that the LED 150 is mounted in the opening 140a of the thin film substrate 140. Therefore, the entire thickness of the LED package 100 is not increased by the presence of the thin film substrate 140 as the heat radiation substrate. Accordingly, the LED package 100 may have a thin structure. Also, since an inexpensive thin film substrate 140 is used, the unit price of the LED package 100 may be reduced.

In addition, although FIGS. 1 to 3 describe the LED package 100 in view of the structure, the LED package 100 may also be described in view of the process. That is, the manufacturing process of the LED package 100 may include bonding the first metal line layer 131 and the second metal line layer 132 onto the circuit substrate 110, forming the opening 140a on the thin film substrate 140 to bond the thin film substrate 140 to the first metal line layer 131 and the second metal line layer 132, and mounting LED 150 in the opening 140a. Thus, a via electrode and a metal line layer may be omitted from the thin film substrate 140, which is the heat radiation substrate, thereby simplifying the process.

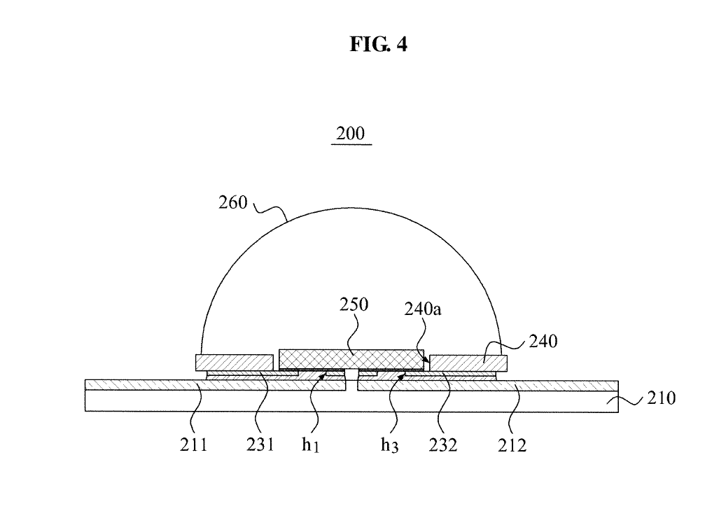

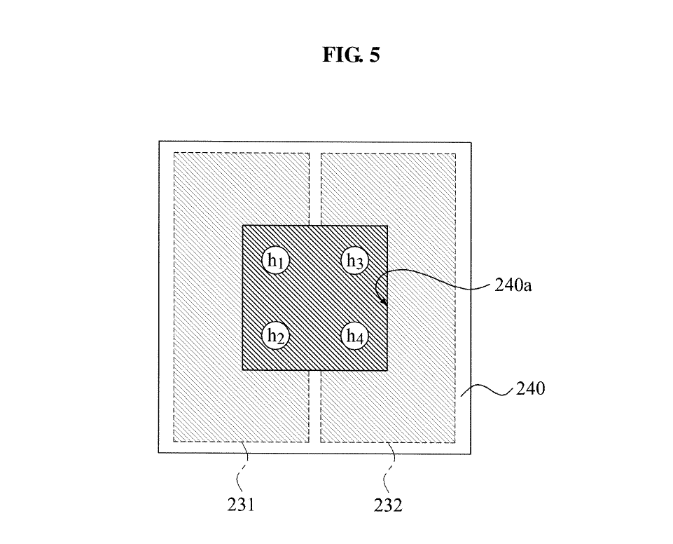

FIGS. 4 and 5 are diagrams illustrating a structure of an LED package 200 according to another embodiment of the present disclosure. FIG. 4 is a sectional view of the LED package 200. FIG. 5 is a plan view showing a thin film substrate 240 mounted on a circuit substrate 210.

Referring to FIG. 4, the LED package 200 includes the circuit substrate 210, a first metal line layer 231, a second metal line layer 232, the thin film substrate 240, an LED 250, and a lens unit 260.

Since the circuit substrate 210, the thin film substrate 240, the LED 250, and the lens unit 260 are structured in the same manner as in the LED package 100 of FIG. 1, a detailed description about the structure will not be repeated for conciseness.

The first metal line layer 231 and the second metal line layer 232 are bonded onto the circuit substrate 210 and connected to circuit patterns 211 and 212. The first metal line layer 231 and the second metal line layer 232 may be disposed at a predetermined distance d₂ from each other on the circuit substrate 210.

The thin film substrate 240 may be mounted on the first metal line layer 231 and the second metal line layer 232 and include an opening 240a providing a region for mounting the LED 250. The first metal line layer 231 and the second metal line layer 232 are exposed through the opening 240a.

As shown in FIG. 5, the first metal line layer 231 and the second metal line layer 232 may include a plurality of holes h₁, h₂, h₃, and h₄ formed in a region exposed through the opening 240a of the thin film substrate 240.

The holes h₁, h₂, h₃, and h₄ may be varied according to a size of the opening 240a. Also, the holes h₁, h₂, h₃, and h₄ may be provided in various shapes, including circles, rectangles, and triangles.

When the LED 250 is mounted in the thin film substrate 240, the LED 250 may be directly bonded to the circuit patterns 211 and 212 of the circuit substrate 210 through the plurality of holes h₁, h₂, h₃, and h₄. In the LED 250, the region bonded to the first metal line layer 231 and the second metal line layer 232 may transfer heat to the circuit substrate 210 through the first metal line layer 231 and the second metal line layer 232. Also, the region bonded to the circuit patterns 211 and 212 through the plurality of holes h₁, h₂, h₃, and h₄ may transfer heat directly to the circuit substrate 210. Accordingly, the LED package 200 may quickly transfer heat to the circuit substrate 210, thereby increasing the heat radiation efficiency.

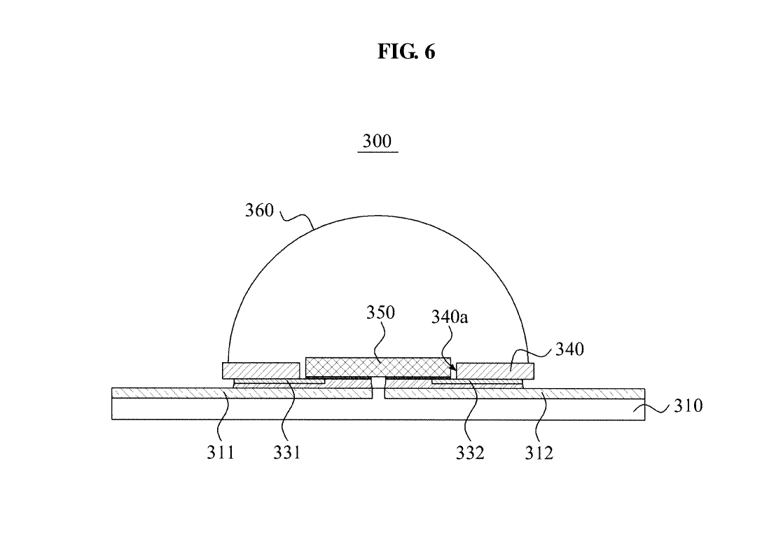

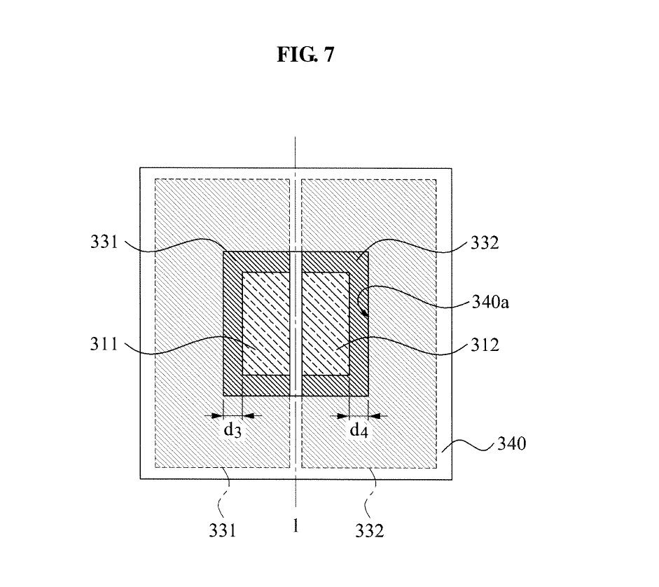

FIGS. 6 and 7 are diagrams illustrating a structure of an LED package 300 according to still another embodiment of the present disclosure. FIG. 6 is a sectional view of the LED package 300. FIG. 7 is a plan view showing a thin film substrate 340 mounted on a circuit substrate 310.

Referring to FIG. 6, the LED package 300 includes the circuit substrate 310, a first metal line layer 331, a second metal line layer 332, the thin film substrate 340, an LED 350, and a lens unit 360.

Since the circuit substrate 310, the thin film substrate 340, the LED 350, and the lens unit 360 are structured in the same manner as in the LED package 100 of FIG. 1, a detailed description about the structure will not be repeated for conciseness.

The first metal line layer 331 and the second metal line layer 332 are bonded onto the circuit substrate 310 and connected to circuit patterns 311 and 312. The first metal line layer 331 and the second metal line layer 332 may be disposed at a predetermined distance from each other on the circuit substrate 310, and exposed at uniform intervals along an inside of an opening 340a of the thin film substrate 340.

More specifically, as shown in FIG. 7, when the thin film substrate 340 is mounted on the circuit substrate 310, the first metal line layer 331 is exposed by a right-open flattened-U shape along the inside of the opening 340a on the left of a reference line I. The first metal line layer 331 exposed by the right-open flattened-U shape may have a uniform width w₁.

The second metal line layer 332 may be exposed by a left-open flattened-U shape on the right of the reference line I. The second metal line layer 332 exposed by the left-open flattened-U shape may have a uniform width w₂. The widths w₁ and w₂ may be the same or different.

As shown in FIGS. 6 and 7, as the first metal line layer 331 and the second metal line layer 332 are exposed at uniform intervals along the inside of the opening 340a, the circuit patterns 311 and 312 included in the circuit substrate 310 may be exposed through a region of the opening 340a where the first metal line layer 331 and the second metal line layer 332 are not formed.

That is, when the LED 350 is mounted in the thin film substrate 340, the LED 350 may be bonded to the circuit substrate 310 directly through a region where the first metal line layer 331 and the second metal line layer 332 are not formed. Compared to the LED packages 100 and 200 shown in FIGS. 1 and 4, the LED 350 may have a larger contact area with the circuit substrate 310, thereby more quickly radiate heat generated from the LED 350 to the outside.

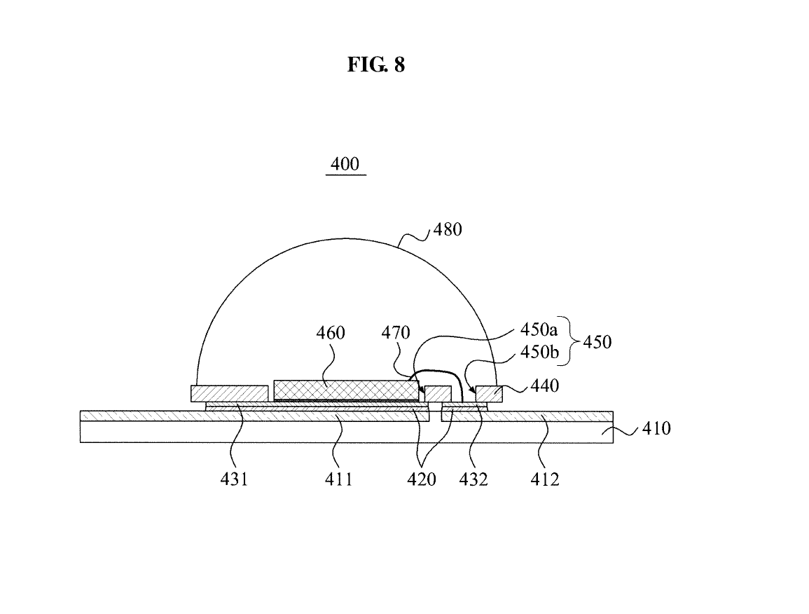

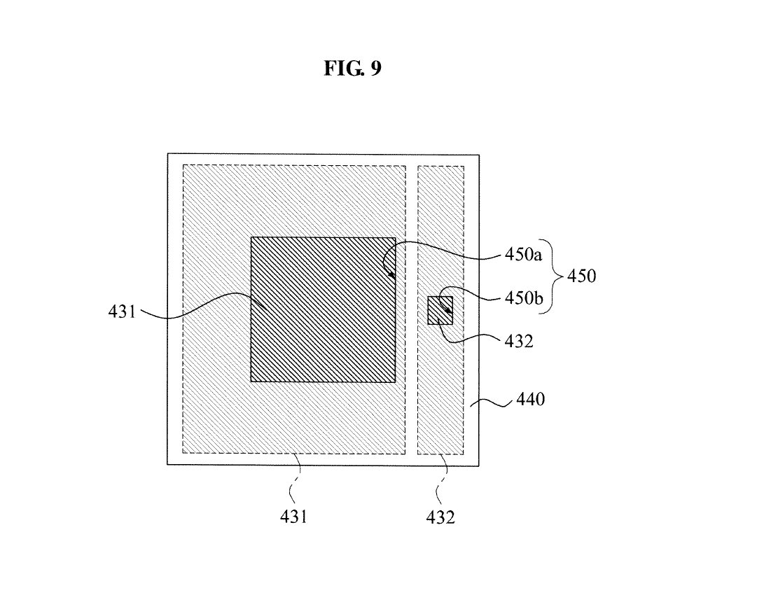

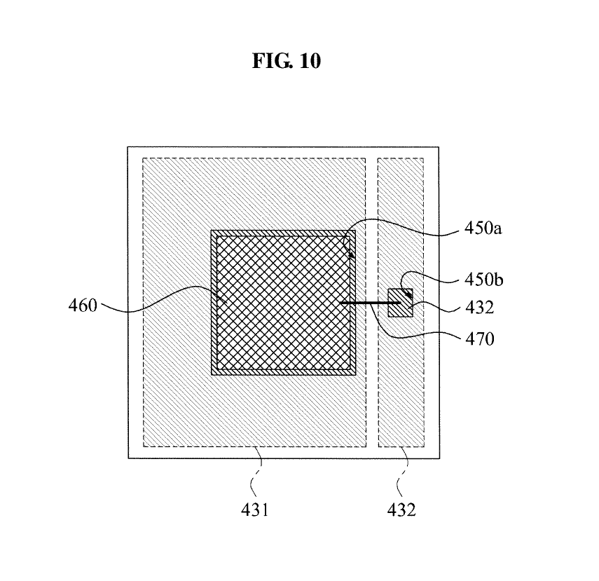

FIGS. 8 to 10 are diagrams illustrating a structure of an LED package 400 according to yet another embodiment of the present disclosure. FIG. 8 is a sectional view of the LED package 400. FIG. 9 is a plan view showing a thin film substrate 440 mounted on a circuit substrate 410. FIG. 10 is a plan view showing an LED 460 mounted in the thin film substrate 440.

Referring to FIG. 8, the LED package 400 includes the circuit substrate 410, a first metal line layer 431, a second metal line layer 432, the thin film substrate 440, the LED 460, and a lens unit 480. The circuit substrate 410 may include circuit patterns 411 and 412 for supplying external power to the LED 460. The first metal line layer 431 and the second metal line layer 432 are bonded onto the circuit substrate 410 through a bonding material 420, and connected with the circuit patterns 411 and 412. The first metal line layer 431 and the second metal line layer 432 are disposed at a predetermined distance from each other on the circuit substrate 410. Here, the first metal line layer 431 and the second metal line layer 432 may have different surface areas.

The thin film substrate 440 may be mounted on the first metal line layer 431 and the second metal line layer 432. In addition, the thin film substrate 440 may include an opening 450 to expose the first metal line layer 431 and the second metal line layer 432. The opening 450 may include a first opening 450a exposing the first metal line layer 431, and a second opening 450b exposing the second metal line layer 432.

Referring to FIG. 9, the first metal line layer 431 is exposed through the first opening 450a and the second metal line layer 432 is exposed through the second opening 450b. Since the first opening 450a supplies a space for mounting the LED 460, the first opening 450a may have a second surface area greater than a first surface area which is a surface area of the LED 460. In addition, to supply a wire bonding space for an electrical connection between the LED 460 and the second metal line layer 432, the second opening 450b may have a third surface area which is less than the first surface area and the second surface area.

Referring to FIG. 10, the LED 460 is mounted in the first opening 450a and electrically connected with the first metal line layer 431. In the present embodiment, the LED 400 has a vertical structure including a first electrode (not shown) disposed on one surface and a second electrode (not shown) disposed on the other surface. Therefore, the first electrode disposed on one surface may be disposed at the first metal line layer 431 whereas the second electrode disposed on the other surface is connected by a wire 470 with the second metal line layer 432 exposed through the second opening 450b.

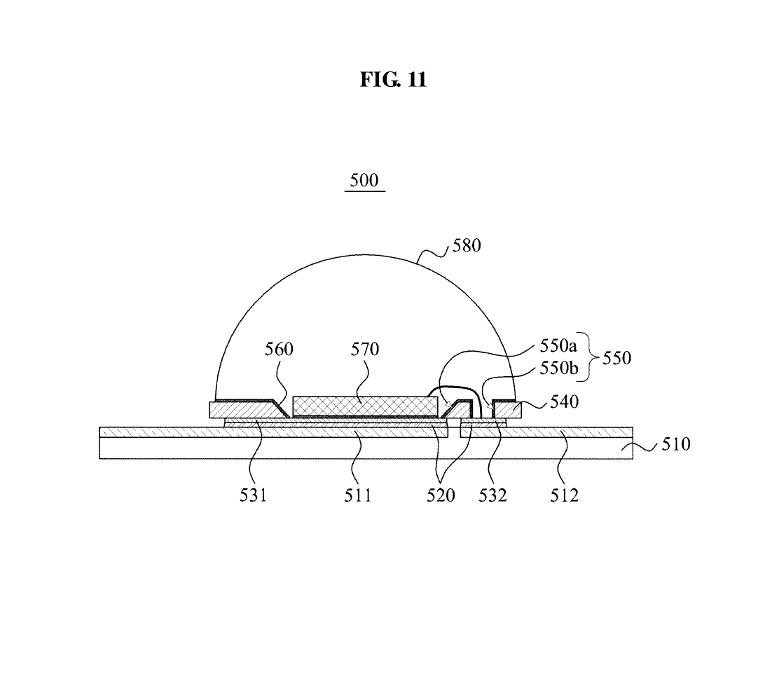

FIG. 11 is a diagram illustrating a structure of an LED package 500 according to another embodiment of the present disclosure. Referring to FIG. 11, the LED package 500 includes a circuit substrate 510, a first metal line layer 531, a second metal line layer 532, a thin film substrate 540, an LED 570, and a lens unit 580. Since the circuit substrate 510, the first metal line layer 531, the second metal line layer 532, the LED 570, and the lens unit 580 are structured in the same manner as in the LED package 400 shown in FIGS. 8 to 10, a detailed description about the structure will not be repeated for conciseness.

The thin film substrate 540 includes a first opening 550a and a second opening 550b. An inner surface of the first opening 550a is inclined toward an upper surface of the thin film substrate 540. According to the inclined structure, light generated from a side surface of the LED 570 is reflected by the thin film substrate 540. As a result, light extraction efficiency is increased. To further increase the light extraction efficiency, a light reflective layer 560 may be further included. Specifically, the light reflective layer 560 may be extended from inner surfaces of the opening 550a and the second opening 550b up to the upper surface of the thin film substrate 540. The light reflective layer 560 may be made of white metal such as aluminum (Al), silver (Ag), and chromium (Cr), or of a metallic material having a high reflectivity.

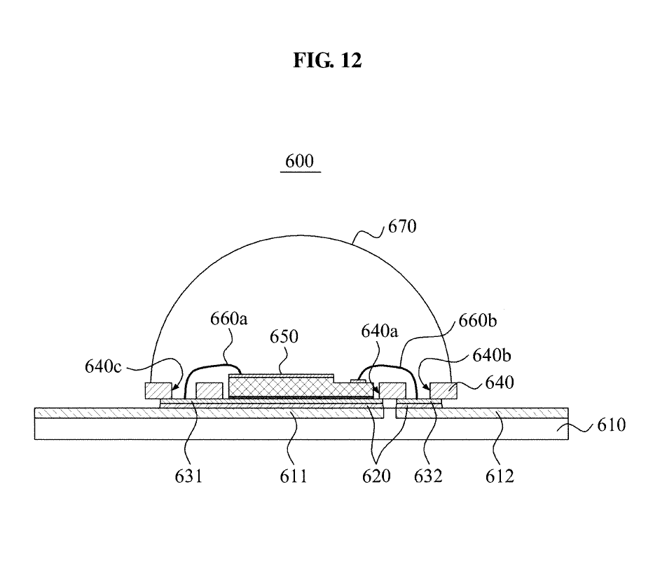

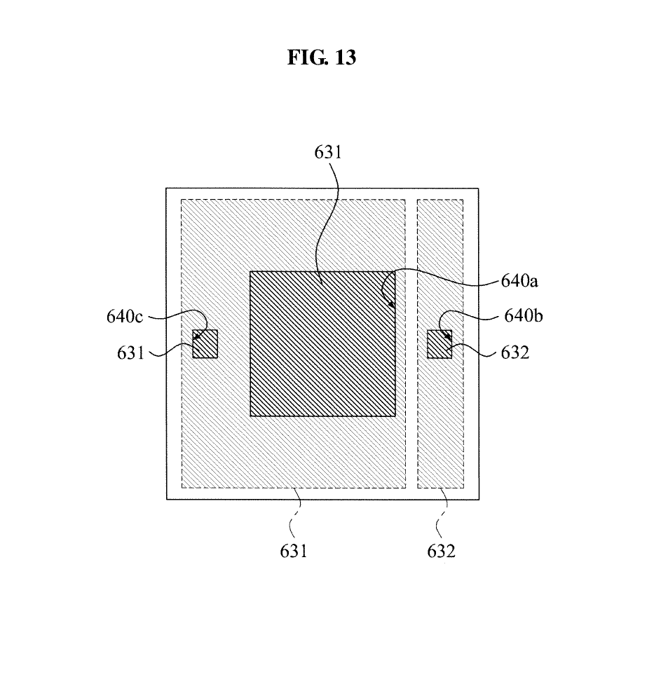

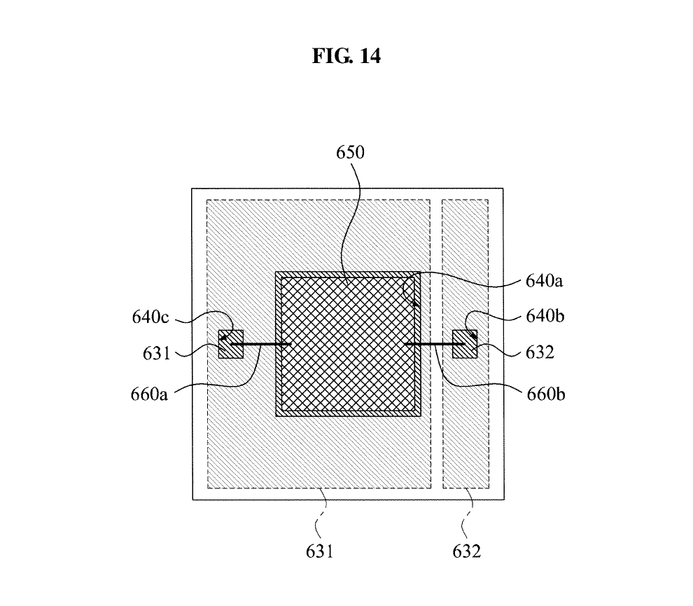

FIGS. 12 to 14 are diagrams illustrating a structure of an LED package 600 according to still another embodiment of the present disclosure. FIG. 12 is a sectional view of the LED package 600. FIG. 13 is a plan view showing a thin film substrate 640 mounted on a circuit substrate 610. FIG. 14 is a plan view showing an LED 650 mounted in the thin film substrate 640.

Referring to FIG. 12, the LED package 600 includes the circuit substrate 610, a first metal line layer 631, a second metal line layer 632, the thin film substrate 640, the LED 650, and a lens unit 670. Since the circuit substrate 610, the first metal line layer 631, the second metal line layer 632, the LED 650, and the lens unit 670 are structured in the same manner as in the LED package 400 shown in FIGS. 8 to 10, a detailed description about the structure will not be repeated. The thin film substrate 640 may be mounted on the first metal line layer 631 and the second metal line layer 632. In addition, the thin film substrate 640 may include first to third openings 640a, 640b, and 640c to expose the first metal line layer 631 and the second metal line layer 632.

Referring to FIG. 13, the first opening 640a exposes the first metal line layer 631 and supplies a space for mounting the LED 650. In addition, the second opening 640b may expose the second metal line layer 643 and provide a wire bonding space for electrically connecting the LED 650 with the second metal line layer 632. In addition, the third opening 540c may expose the first metal line layer 631 and provide a wire bonding space for electrically connecting the LED 650 with the first metal line layer 631.

Referring to FIG. 14, the LED 650 is mounted in the first opening 640a. The LED 650 has an epi-up structure in that a first electrode (not shown) and a second electrode (not shown) are horizontally disposed on a coplanar surface. A first wire 660a may be bonded to the first electrode and the first metal line layer 631 of the LED 650. A second wire 660b may be bonded to the second electrode and the second metal line layer 632 of the LED 650.

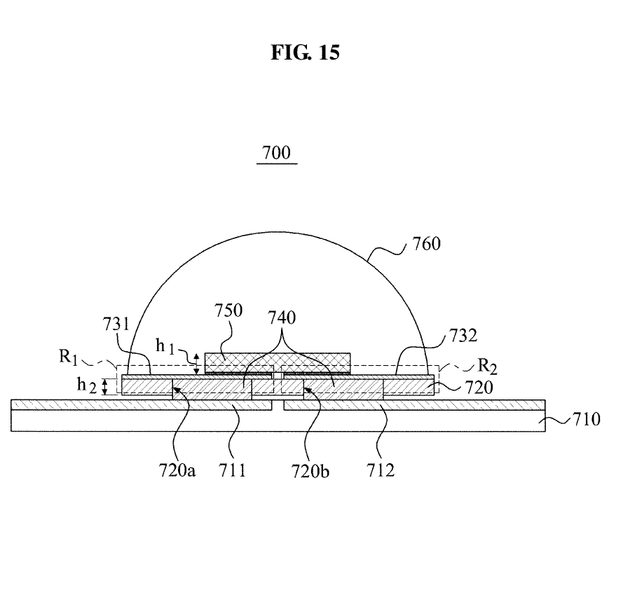

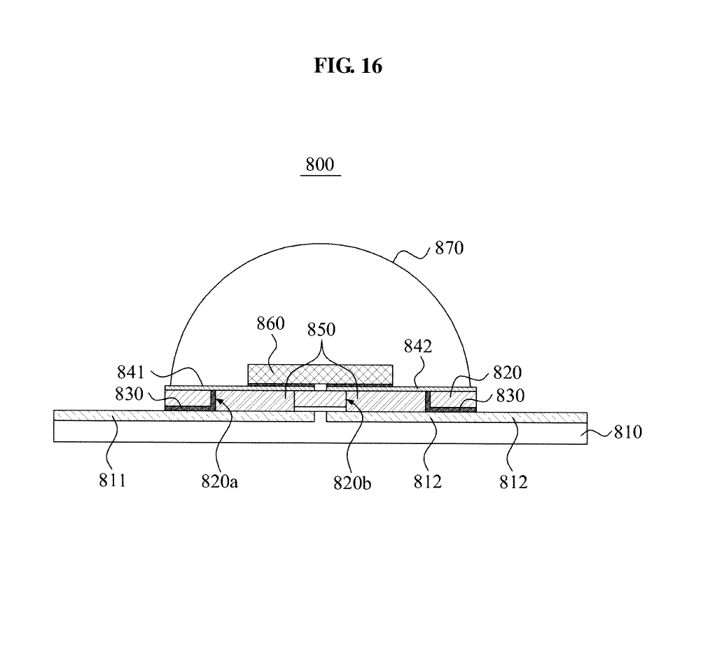

FIGS. 15 and 16 are diagrams illustrating structures of LED packages according to various embodiments of the present disclosure. Referring to FIG. 15, an LED package 700 includes a circuit substrate 710, a thin film substrate 720, a first metal line layer 731, a second metal line layer 732, an LED 750, and a lens unit 760. The first substrate 710 may include circuit patterns 711 and 712 to supply external power to the LED 750. The thin film substrate 720 may be mounted on the circuit substrate 710, and include a first opening 720a and a second opening 720b for exposing the circuit patterns 711 and 712 of the circuit substrate 710.

The thin film substrate 720 may be formed of any one selected from a polyimide, an epoxy resin, a silicone resin, PET resin, a polyester resin, and a ceramic. The thin film substrate 720 may further include a glass fiber or a ceramic powder to increase hardness or supplement mechanical property.

The first metal line layer 731 and the second metal line layer 732 may be bonded onto the thin film substrate 720 and disposed at a distance from each other. The first metal line layer 731 may be bonded to a first region R₁ including the first opening 720a while the second metal line layer 732 is bonded to a second region R₂ including the second opening 720b. A metal bonding layer 740 fills in the first opening 720a and the second opening 720b, thereby electrically connecting the first metal line layer 731 and the second metal line layer 732 to the circuit substrate 710.

The LED 750 may be mounted on the first metal line layer 731 and the second metal line layer 732. The LED 750 may be flip-chip bonded. A first electrode (not shown) of the LED 750 is bonded to the first metal line layer 731. A second electrode (not shown) of the LED 750 is bonded to the second metal line layer 732. The lens unit 760 is disposed on the first metal line layer 731 and the second metal line layer 732, thereby covering the LED 750. Although the LED 750 is illustrated and described as being flip-chip bonded in FIG. 15, the LED 750 may be electrically connected with the first metal line layer 731 and the second metal line layer 732 by wire-bonding.

Although not shown, a high-reflectivity metal layer may be applied to an upper portion of the first metal line layer 731 and the second metal line layer 732 so as to increase the light extraction efficiency.

In the embodiment shown in FIG. 15, the thin film substrate 720 may have a second height h₂ lower than a first height h₁, which is the height of the LED 750. Specifically, since the thin film substrate 720 may have a thickness of at least about ten micrometers (μm), the entire thickness of the LED package 700 may be reduced compared to a conventional LED package using a ceramic substrate as a heat radiation substrate.

Also, the LED package 700 transfers heat generated from the LED 750 to the metal bonding layer 740 through the first metal line layer 731 and the second metal line layer 732, and finally to the circuit substrate 710. Thus, the heat may be quickly radiated to the outside.

Referring to FIG. 16, an LED package 800 includes a circuit substrate 810, a thin film substrate 820, a first metal line layer 841, a second metal line layer 842, an LED 860, and a lens unit 870. The LED package 800 shown in FIG. 16 has almost the same structure as the LED package 700 of FIG. 15. However the LED package 800 further includes a metal pattern layer 830 disposed on a lower surface of the thin film substrate 820.

When a metal bonding layer 850 is put in the first opening 820a and the second opening 820b of the thin film substrate 820, a region of the metal bonding layer 850 where the first opening 820a and the second opening 820b are not formed is separated from circuit patterns 811 and 812 due to the thickness of the metal bonding layer 840. Therefore, the metal pattern layer 830 may be provided at the lower surface of the thin film substrate 820 to increase a contact area between the thin film substrate 820 and the circuit patterns 811 and 812.

The metal pattern layer 830 may be extended from an outer surface of the thin film substrate 820 up to insides of the first opening 820a and the second opening 820b, passing through a bonding surface of the circuit substrate 810. As a bonding area between the thin film substrate 820 and the thin film substrate 810 increases, a heat transfer area is increased, consequently the heat radiation efficiency is increased.

Although a few exemplary embodiments have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A light emitting diode (LED) package comprising:
a first metal line layer and a second metal line layer bonded to a circuit substrate;
a thin film substrate disposed on the first metal line layer and the second metal line layer and including an opening that exposes the first metal line layer and the second metal line layer; and
an LED disposed in the opening and contacting the first metal line layer and the second metal line layer.

2. The LED package of claim 1, wherein the thin film substrate has a second height equal to or less than a first height, which is, a height of the LED.

3. The LED package of claim 1, wherein the thin film substrate has a second height greater than a first height, which is a height of the LED.

4. The LED package of claim 1, wherein the opening has a second surface area greater than a first surface area, which is a surface area of the LED.

5. The LED package of claim 3, further comprising a light reflective filling material disposed between the opening and the LED.

6. The LED package of claim 4, wherein the light reflective filling material comprises an organic or inorganic polymer, a light reflective material, a reinforcing material, an adhesive, and an antioxidant.

7. The LED package of claim 1, wherein the first metal line layer and the second metal line layer are disposed at a predetermined distance from each other on the circuit substrate.

8. The LED package of claim 7, wherein the first metal line layer and the second metal line layer each comprise a plurality of holes disposed on an exposed region of the thin film substrate, exposed through the opening, to expose the circuit substrate.

9. The LED package of claim 1, wherein the first metal line layer and the second metal line layer are disposed on a front surface of the circuit substrate at a distance from each other, and exposed at uniform intervals along an inside of the opening of the thin film substrate.

10. The LED package of claim 1, wherein the opening comprises:
a first opening to expose the first metal line layer; and
a second opening to expose the second metal line layer.

11. The LED package of claim 10, wherein the LED is disposed in the first opening and electrically connected with the first metal line layer, and also electrically connected with the second metal line layer exposed through the second opening by a wire.

12. The LED package of claim 10, wherein the opening further comprises a third opening to expose the first metal line layer.

13. The LED package of claim 12, wherein the LED is disposed in the first opening and electrically connected with the second metal line layer exposed through the second opening by a first wire, and also electrically connected with the first metal line layer exposed through the third opening by a second wire.

14. The LED package of claim 1, wherein an inner surface of the opening is inclined toward an upper surface of the thin film substrate.

15. The LED package of claim 1, further comprising a light reflective layer extending from an inner surface of the opening to an upper surface of the thin film substrate.

16. The LED package of claim 1, further comprising a lens unit disposed on the thin film substrate to cover the LED.

17. The LED package of claim 1, wherein the thin film substrate comprises any one of a polyimide, an epoxy resin, a silicone resin, polyethylene terephthalate (PET) resin, a polyester resin, and a ceramic.

18. A light emitting diode (LED) package comprising:
a circuit substrate;
a thin film substrate disposed on the circuit substrate and including a first opening and a second opening exposing the circuit substrate;
a first metal line layer and a second metal line layer bonded to the thin film substrate, and respectively disposed in a first region which includes the first opening and a second region which includes the second opening;
a metal bonding layer filling in the first opening and the second opening, thereby electrically connecting the first metal line layer and the second metal line layer with the circuit substrate; and
an LED disposed on the first metal line layer and the second metal line layer.

19. The LED package of claim 18, further comprising a metal pattern layer extended from an outer surface of the thin film substrate to inner surfaces of the first opening and the second opening, passing through a bonding surface with respect to the circuit substrate.

20. The LED package of claim 18, further comprising a lens unit disposed on the thin film substrate to cover the LED.
